(19) United States
(12) Patent Application Publication
(10) Pub. No.: US 2018/0261269 A1
(43) Pub. Date: Sep. 13, 2018

(54) THREE-DIMENSIONAL MRAM CELL CONFIGURATIONS

(71) Applicant: Jannier Maximo Roiz Wilson, Santa Clara, CA (US)

(72) Inventor: Jannier Maximo Roiz Wilson, Santa Clara, CA (US)

(21) Appl. No.: 14/588,819

(22) Filed: Jan. 2, 2015

(51) Int. Cl. G11C 11/16; H01L 27/22; H01L 43/02; H01L 43/10; H01L 43/12

(52) U.S. Cl. CPC G11C 11/161; H01L 27/226; H01L 43/12; H01L 43/02; H01L 43/10; G11C 11/1659

(57) ABSTRACT

The present invention sets forth a new approach to Spin Transfer Torque MRAM that relies on 3D shape anisotropy and bulk-like ferromagnetic material properties in the free-layer to lower the write current and allow high TMR to a great extent independently of cell size and for any desired thermal stability of the cell.

### FIELD

Embodiments of the present invention relate to Spin Transfer Torque Magnetic Random Access Memory cell configurations relying on non-planar shape anisotropy for thermal stability and normally having extra magnetostatically-coupled magnetic elements that are switched through field-induced switching by the spin-torque-switched free-layer.

### BACKGROUND

When it comes to spin transfer torque magnetic random access memory (STT-MRAM) there have been two main approaches, which are, in-plane STT-MRAM and perpendicular STT-MRAM or pSTT-MRAM. Despite being far more successful than other MRAM approaches they still face very significant challenges. Some of the major ones are related to memory cell scaling, like lowering the write current to fit minimum (or small enough) transistor size and to lower energy consumption and getting enough thermal stability at the low 2× nm nodes and below. All that while still attaining high enough tunneling magneto-resistance (TMR) in the cell's magnetic tunnel junction (MTJ) for fast and reliable reading.

In-plane STT-MRAM, due to its thin film geometry, has to contend with enormous out-of-plane demagnetizing fields that keep the switching current unacceptably high for most applications. The more promising perpendicular STT-MRAM solves that problem with its perpendicular anisotropy, but still the write current remains unsuitably high. And that is due to high damping that derives from the way the perpendicular anisotropy is obtained, which is through the magnetic properties of certain materials and interfaces in very thin film geometries. Also, with material-based anisotropy it is difficult to attain the required thermal stability of the cell when scaling down to smaller dimensions, as the energy barrier decreases rapidly with the cell's free-layer area. On top of that, the materials combination and geometries still need to attain high enough TMR, which is by no means a given. Furthermore, even if the dampening in the free-layer of pMRAM cells were managed somehow to be suitably small along with the write current, that achievement would bring up problems with the speed and write-error rate of the memory device, as the magnetization in the free-layer would ring long and swing wildly due to its low dampened motion.

The inventions herein described, simultaneously give solutions to all those issues with yet a new approach to STT-MRAM.

### SUMMARY

The present invention encompasses a multitude of Three-dimensional Spin Transfer-Magnetic Random Access Memory (3D-MRAM) cell configurations. The three dimensional aspect arises from the way magnetic anisotropy is obtained in the cells in order to achieve thermal stability. Nominally, the magnetic anisotropy is not produced by crystalline anisotropy or any surface-induced anisotropy but by shape anisotropy with non-planar geometry in the free-layer. The free-layer has comparable dimensions in two of the main axis, producing some isotropy in those planes, and somewhat larger dimension in the anisotropy direction. Hence, the free-layer geometry has a three-dimensional aspect to it. Furthermore, most of the cell configurations have additional magnetic elements magnetostatically coupled to the free-layer that add to the three-dimensionality of the cells. These magnetic elements or magnetic shields are switched by the magnetic field associated to the free-layer, which in turn is switched by spin torque transfer. The magnetic shields help reducing the cell's stray field and help making the switching event shorter and more deterministic and the cell more thermally stable. Eliminating or reducing as much as possible the crystalline, the interface and the planar anisotropies allows lowering the switching current to unprecedented lows as the dampening factor can be very small, both through unprecedentedly small damping constant, close to bulk values, and through small anisotropy field. At the same time, the thermal stability of the cell does not depend on cell size and it is decoupled from magneto-resistance, which allow for simultaneous optimization of switching current, thermal stability and magneto-resistance in a wide range of cell size.

### CITATIONS

[1]. A. Natarajathinam et al, J. Appl. Phys. 111, 07C918 (2012).
[2]. M. Gajek et al, App. Phys. Letters 100, 132408 (2012)).

### BRIEF DESCRIPTION OF THE DRAWINGS

FIG. 1. Cell 1 configuration, A) shown across the bit-line, B) shown along the bit-line. The arrows represent one example of stable net magnetization of the ferromagnetic layers.

FIG. 2. Two-layer structure of the 3D-free-layer. The magnetizations of layers 12 and 13 are ferromagnetically coupled. The solid-line arrows and the dotted arrows represent the two stable configurations of the magnetizations by pairs.

FIG. 3. Top view of a MTJ showing with arrows the stable net magnetizations of the free (from layer 1) and fixed layers (from layers 3 and 5). The fixed-layer magnetization is preferably tilted respect to the easy axis.

FIG. 4. Cell 2 configuration, A) shown across the bit-line, B) shown along the bit-line. The arrows represent the stable net magnetization of the ferromagnetic layers.

FIG. 5. Two-layer structure of the free-layer of Cell 2. The magnetizations of layers 12 and 13 are ferromagnetically coupled.

FIG. 6. Cell 3 configuration, A) shown across the bit-line, B) shown along the bit-line. The arrows represent one example of stable net magnetization of the ferromagnetic layers.

FIG. 7. A second embodiment of Cell 3 configuration, A) shown across the bit-line, B) shown along the bit-line. The arrows represent one example of stable net magnetization of the ferromagnetic layers different from the embodiment of FIG. 6. The dotted arrow represents the magnetization of the magnetic shield 14 at the back.

FIG. 8. Cell 4 configuration, A) shown across the bit-line, B) shown along the bit-line. The arrows represent one example of stable net magnetization of the ferromagnetic layers.

FIG. 9. Cell 5 configuration, A) shown across the bit-line, B) shown along the bit-line. The arrows represent one example of stable net magnetization of the ferromagnetic layers.

FIG. 10. Another embodiment of Cell 5 configuration with the bit-line oriented 90° respect to the embodiment shown in FIG. 9. In principle, the bit-line can have any in-plane orientation respect to the MTJ.

FIG. 11. Cell 6 configuration, A) side view across the bit-line, B) Top-down view for circular-shaped free-layer; the bit line position is outlined with a dashed line, C) Top-down view for square-shaped free-layer; the bit line position is also outlined with a dashed line.

### DETAILED DESCRIPTION

In the following description, for purposes of explanation, numerous specific details are set forth in order to provide a thorough understanding of the invention. It will be apparent, however, to one skilled in the art that the invention can be practiced without these specific details.

Reference in this specification to “one embodiment” or “an embodiment” or “some embodiments” means that a particular feature, structure, or characteristic described in connection with the embodiment is included in at least one embodiment of the invention. The appearance of the phrase “in one embodiment” or “some embodiments” in various places in the specification are not necessarily all referring to the same embodiment(s), nor are separate or alternative embodiments mutually exclusive of other embodiments. Moreover, various features are described which may be exhibited by some embodiments and not by others. Similarly, various requirements are described which may be requirements for some embodiments but not other embodiments.

Although the following description contains many specifics for the purposes of illustration, one skilled in the art will appreciate that many variations and/or alterations to said details are within the scope of the present invention. Similarly, although many of the features of the present invention are described in terms of each other, or in conjunction with each other, one skilled in the art will appreciate that many of these features can be provided independently of other features. Accordingly, this description of the invention is set forth without any loss of generality to, and without imposing limitations upon, the invention.

In most STT-MRAM cell configurations there are tradeoffs that must be made that hamper the further lowering of the switching current and/or limit the magnitude of change in cell resistance when switching between the two stable states (in other words, limit the magneto-resistance ratio or MR ratio). In-plane STT-MRAM configurations rely on a thin magnetic free-layer with an inherent out of plane demagnetizing field component that dwarfs any magnetic field component due to in-plane shape anisotropy. This large uncompensated out of plane component keeps the switching current relatively large. Perpendicular STT-MRAM configurations avoid this problem but the need for large perpendicular crystalline or interface anisotropy to achieve the thermal stability of the cell, normally brings a relatively large damping coefficient associated with it, which also prevents further lowering the switching current. The required large perpendicular crystalline or interface anisotropy also makes it challenging to obtain the large MR ratio needed for fast and reliable reading operations, as it puts constrains on materials, annealing temperature and thicknesses. In both in-plane and perpendicular STT-MRAM, lowering the free-layer's damping coefficient to produce the lowering of the switching current produces longer die-down precessions of the free-layer's magnetization and higher likelihood of miswrite through unintended switch-backs of the magnetization during the write event. The present invention gives solutions to these issues without resorting to new materials, and allows the simultaneous reduction of the switching current, the optimization of the MR ratio and the increasing of speed and determinism of the switching event.

The cells comprised in the present invention, like conventional STT-MRAM cells, use the spin transfer torque mechanism for switching. However, they rely on geometry to reduce or totally eliminate the issue of the large out of plane demagnetizing field that affects in-plane STT-MRAM, which keeps the write current relatively high. This is achieved by changing the geometry of the free-layer from thin and flat to thick 3D kind of geometry where there is not a flatten shape that would induce an easy plane anisotropy. As to the overall shape of the free-layer, there is no stringent constraint on it, as long as the shape does not produce any significant magnetic anisotropy other than the uniaxial magnetic anisotropy needed for the thermal stability of the cell. For example, in some embodiments the free-layer may have rounded edges as seen from a top-down view; in others, those edges may be sharp.

Having the free-layer anisotropy dependent only on shape and saturation magnetization allows decoupling its damping constant, its size and its MR ratio from the thermal stability of the cell. Therefore, these parameters can be simultaneously optimized to attain the lowest possible switching current with high enough MR ratio in any practical size node below 45 nm; no tradeoff involved. Another key advantage of a thick free-layer is that the damping coefficient can be far lower than in thin free layers. That is because the thick free-layer behaves close to a bulk ferromagnetic layer for which the damping constant is far lower than for a thin layer (e.g. <2 nm) of the same material.

This new kind of free-layer is herein dubbed a 3D-free-layer and it is a key characteristic of all the cells presented in this disclosure. Having that in mind, in this text, the 3D-free-layers will sometimes be simply referred to as free-layers, as its overall function is no different to the function of free layers in conventional MRAM cells. By association, the MRAM cells relying on 3D-free layers are herein named 3D-MRAM cells.

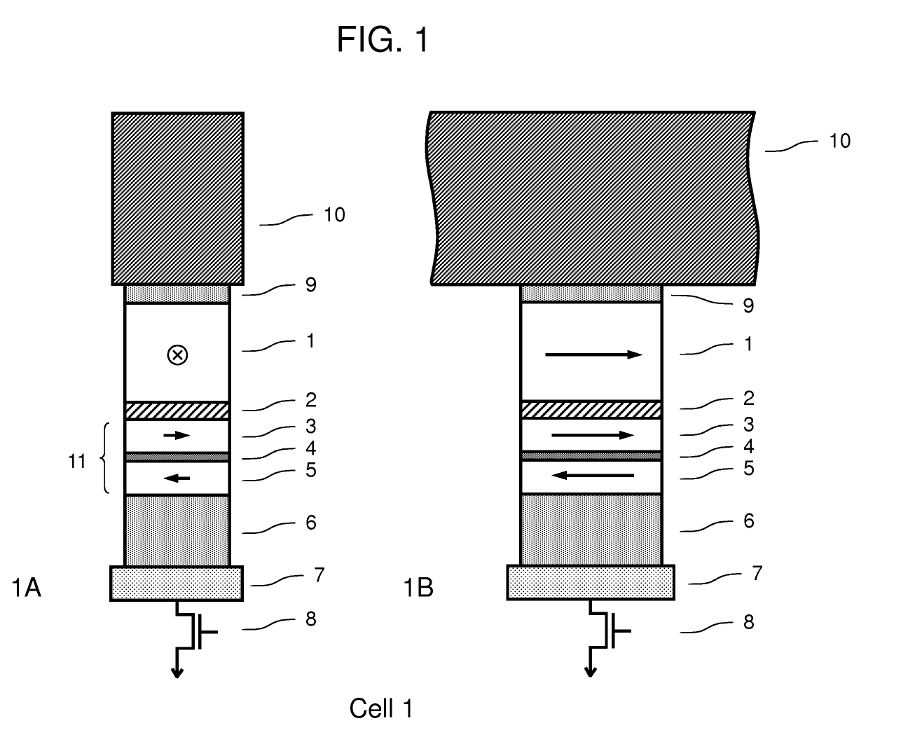

The simplest embodiment of a 3D-MRAM cell is shown in Cell 1 (FIG. 1). In one embodiment, the 3D-free-layer of Cell 1 is composed of a single ferromagnetic layer that it is as thick as it is wide, forming a squarish cross section, thus eliminating the easy-plane anisotropy characteristic of the free layers of in-plane STT-MRAM cell configurations. With this geometry, the large out of plane demagnetizing field is no longer a factor weighing on the switching current, which is now only a factor of the thermal stability and of any strayed field acting on the free-layer. In some embodiments this layer can be composed of CoFeB alloys in other is composed of Heusler alloys, but it is not limited to these two cases.

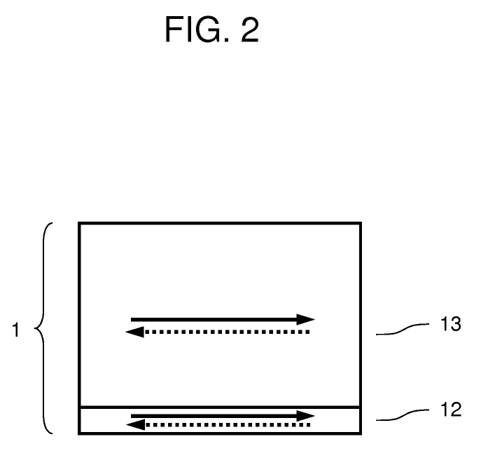

With the same 3D principle in mind, in another embodiment, the 3D-free-layer is composed of two exchange-coupled ferromagnetic layers 12 and 13, as shown in FIG. 2. The layer closest to the tunneling layer 12 is thin and optimized for high MR ratio. An example of this layer is one of less than 2 nm thick, composed of a CoFeB alloy. With this material, the objective is to produce epitaxial bcc (001) CoFe on bcc (001) MgO during annealing, to obtain high MR ratio. The second layer 13 is the thickest one and it is responsible for reducing the net magnetization, through lower saturation magnetization (Ms) than layer 12, and responsible for reducing the damping coefficient of the free-layer as compared to a single-layer free-layer through low damping coefficient materials. Examples of this layer are a layer of CoFeSiB or Permalloy, thick enough to reduce or basically eliminate the easy-plane anisotropy. In this way, it is possible to reduce the bit-to-bit magnetostatic disturb and damping coefficient of the free-layer while keeping high the MR ratio.

In other embodiments the 3D-free-layer is a bit flatter (it is a bit wider than thicker). That would not eliminate the easy-plane anisotropy of the free-layer but it would reduce it compared to a much flatter geometry. Although this approach would not allow switching currents as small as in the previous case, the somewhat less tall cell would make easier the manufacturing of the cell, especially for dimensions larger than 30 nm.

As with conventional in-plane STT-MRAM cells, Cell 1 contains a magnetic tunnel junction (MTJ, which encompasses all the numbered elements in FIG. 1, except for 8 and 10) which has a free-layer 1 (in this case a 3D-free-layer). It has a tunneling layer 2, which is composed of a dielectric material, preferably MgO. The MTJ also has a fixed-layer 11 which is a synthetic anti-ferromagnet (SAF) with the magnetization pinned in a defined direction by an anti-ferromagnet layer 6 through exchange bias. The SAF is composed of two ferromagnetic layers 3 and 5, anti-ferromagnetically coupled through a thin non-magnetic metallic spacer layer 4 (usually Ru). In some embodiments, layers 3 and 5 are composed of CoFe and CoFeB alloys. For example: layer 3 is a layer of CoFeB/CoFe and layer 5 is a layer of CoFe with many different stoichiometries and thicknesses. A preferred composition for the CoFeB layer is Co_{0.4}Fe_{0.4}B_{0.2} and for the CoFe layer is Co_{0.7}Fe_{0.3}. The magnetization of these layers should be such that the net stray field of the fixed-layer on the free-layer is minimized. The preferred compositions for the anti-ferromagnet 6 are PtMn and IrMn, but it is not limited to just these two. Normally, the thickness of this layer is chosen to provide large enough exchange field to keep the fixed-layer magnetization from moving so to noticeably affect the write and read processes. The MTJ also has a bottom electrode 7 which is a seed layer as well. The composition of this layer can be very varied but combinations with Ta on top are preferred; as for example: Ta, Ta/Ru/Ta, Ta/CuN/Ta. On the top of the MTJ stack there is electrode 9 (usually composed of Ta or Ru or Ta/Ru) and at the bottom of the cell there is an access transistor 8, the drain of which is connected to the cell's MTJ. In a memory setting, the cell is connected on top to a bit-line 10. A word-line would connect to the access transistor's gate and a source-line would connect to the access transistor's source. The materials provided in this document are given as examples and by no means are intended to limit the choice of material composition of any specific layer.

The switching mechanism is conventional STT (found elsewhere) that requires bipolar current to flow through the MTJ to switch the free-layer's magnetization in one sense or the opposite of the fixed-layer's magnetization. The fixed-layer acts as the spin polarizer for the electrons that transfer their spin into the free-layer.

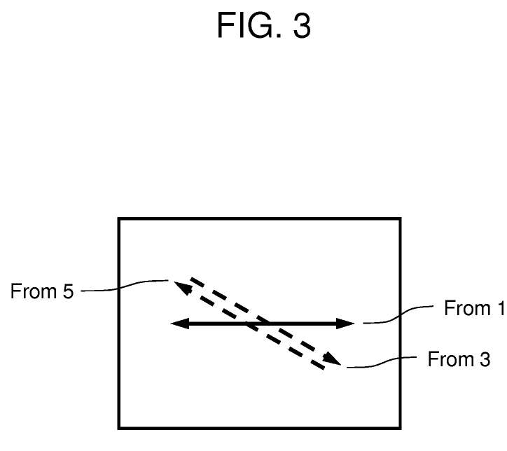

The magnetizations in the fixed-layer are either fixed in the direction of the free-layer's easy axis (parallel alignment) or forming some angle with it (angled alignment), preferably smaller than ±45 degrees (or between 135 and 225 degrees, depending on the frame of reference) and laying in-plane, as shown in FIG. 3. The latter case has a significant advantage over the parallel one, as it produces a faster and more deterministic switching of the cell and reduces the switching current. That is due to non-zero spin transfer torque from the start of the switching event, which eliminates any uncertain thermal incubation delay. To obtain an angled alignment the fixed-layer needs to be annealed in the presence of magnetic field oriented in the intended direction, at a temperature above the blocking temperature of the anti-ferromagnetic material. The annealing step can be performed at any time after the deposition of the anti-ferromagnetic and the fixed layers.

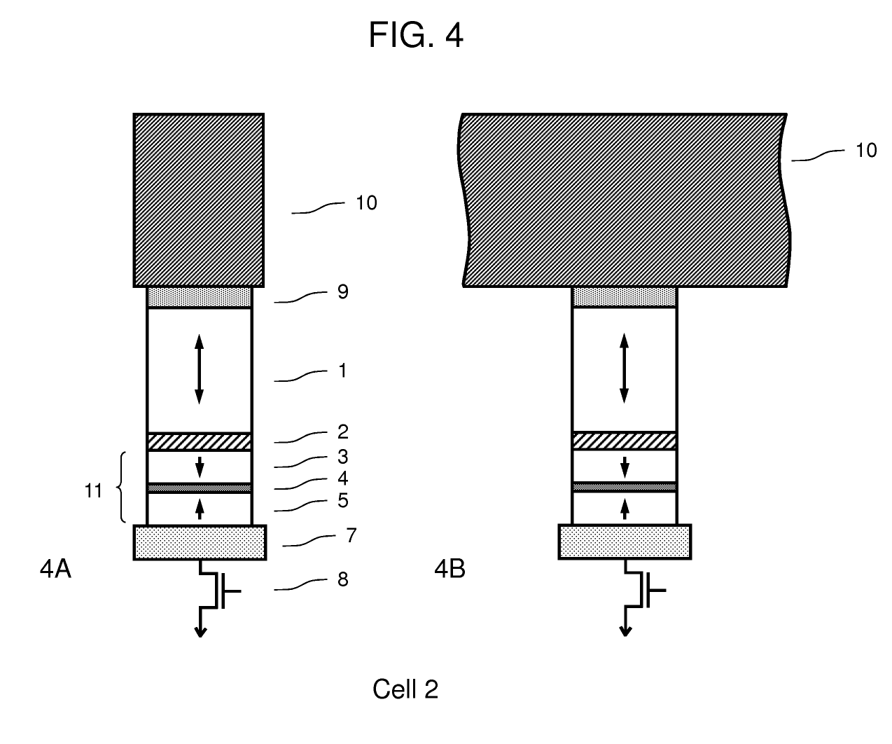

The Cell 1 concept can also be practiced in a perpendicular orientation, as shown in Cell 2 in FIG. 4. From the figure it can be seen that Cell 2 has the same elements as Cell 1, except for the anti-ferromagnetic layer 6. Unlike cells with in-plane orientation, the cells with perpendicular orientation do not rely on an anti-ferromagnet to fix the magnetization of the fixed-layer. Instead, they rely on the strong perpendicular anisotropy of the fixed-layer. Such strong anisotropy can be obtained with Co/M multilayers, where M can be Pt, Pd, Ni, Cu, Au, among other metals. The structure of the perpendicular SAF fixed-layer is usually more complex than for the in-plane case and may impose more constraints on layer thicknesses and on annealing temperature. Examples of such SAFs can be found in references [1] and [2].

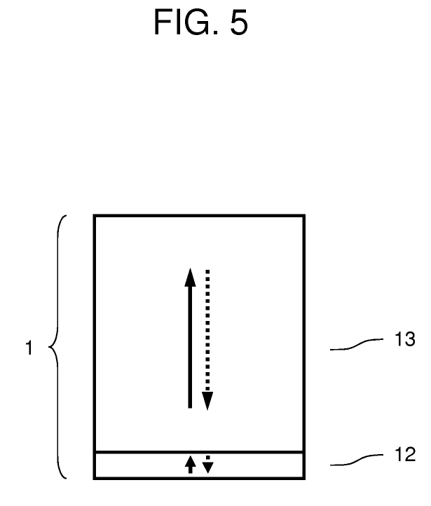

The perpendicular orientation allows somewhat larger memory density as its MTJ occupies less area and its magnetostatic disturb is lower than in the in-plane orientation case. As the cells with in-plane orientation, the cells with perpendicular orientation allow to simultaneously optimize the free-layer for high MR ratio and low damping constant, regardless of the thermal stability. For that, like in Cell 1, the free-layer in Cell 2 can be divided in the two ferromagnetic layers 12 and 13, as shown in FIG. 5, to better optimize MR ratio, Ms and damping constant.

Cell 1, like in-plane STT-MRAM cell configurations, has the advantage of counting on well known materials that already allow high MR ratio and low damping constant. However, unlike in-plane STT-MRAM cell configurations, Cell 1 does not have the disadvantage of relatively large switching current produced by the easy-plane anisotropy in the free-layer. Cell 1 has the disadvantage though of higher magnetostatic disturb that may lead to larger bit to bit distance and lower memory density. The perpendicular approach of Cell 2 also has that problem but to a lesser extent. Although the magnetostatic disturb can be significantly reduced by reducing the overall saturation magnetization Ms of the free-layer through dividing the free-layer in the layers 12 and 13 discussed above, the magnetostatic disturb would still be somewhat significant. The ensuing cell configurations address this problem by reducing the magnetostatic disturb much further.

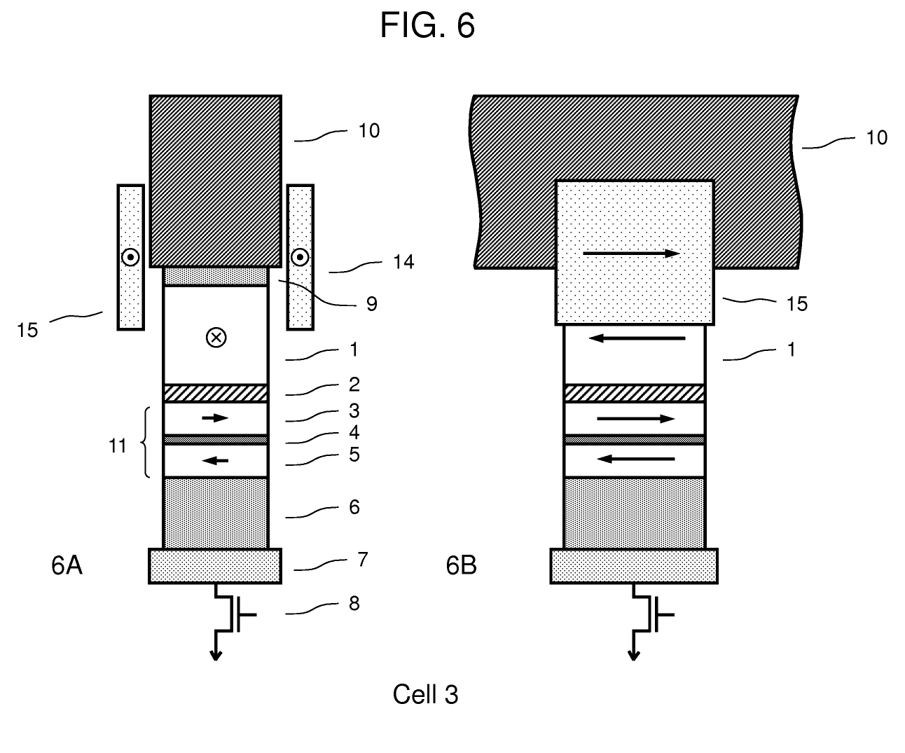

The magnetostatic disturb is significantly reduced through the inclusion of magnetic side elements to the cell in close proximity to the free-layer. These side elements, herein dubbed magnetic shields, do not carry electric current and have no significant exchange interaction with the free-layer but their magnetizations establish a magnetostatic closed-loop field with the free-layer that allows significant reduction of the stray magnetic field of the cell. One embodiment of this concept is represented as Cell 3, in FIG. 6. The magnetizations of the magnetic shields 14 and 15 are anti-ferromagnetically coupled to the free-layer. Obviously, the magnitude of the magnetization of the magnetic shields would be set to significantly reduce the stray field of the cell.

Cell 3 structure is like Cell 1 except for the magnetic shields. As with Cell 1, in some embodiments, the magnetization in the fixed-layer of Cell 3 is set to form an angle different from 0 or 180 degrees with the equilibrium magnetization of the free-layer. In other embodiments that angle can be 0 or 180 degrees. In some embodiments the free-layer is composed of one single layer. In other embodiments the free-layer is composed of the two layers 12 and 13, as in Cell 1.

During the cell switching event, the magnetization of the free-layer and the magnetic shields switch closely in unison in opposite orientation. While the switching of the free-layer is driven by spin transfer torque, the switching of the magnetic shields is driven by the magnetic field associated to the free-layer. Obviously, the coupling magnetic field between these layers must be significantly larger than the switching field of the magnetic shields. That is controlled through the shape anisotropy and magnetic moment of the magnetic shields.

The magnetic shields not only help reduce the magnetostatic disturb but also have other functions. One of the functions is to damp down the precession of the free-layer's magnetization. For that, the magnetic shields must be composed of a ferromagnetic layer or a composite with high damping constant. Larger damping constant makes the field-induced switching of the magnetic shields faster, more deterministic and more robust. At the same time, the damping constant of the free-layer can be as small as it can get, which not only would reduce the switching current of the cell but it would allow the free-layer to switch faster. The switch however would be short and quickly damped down by the magnetic shields. It should be noticed that the center of the magnetic shields lies above the center of the free-layer; that is to help damping down the in-plane component of the precession of the free-layer's magnetization. This is because the in-plane movement of the free-layer's magnetization would be coupled to the dampened up-and-down movement of the magnetization in the magnetic shields. Another function of the magnetic shields is to add determinism to the switching process, which is a byproduct of the previous function. A third function of the magnetic shields is to add thermal stability to the cell. That is achieved through the shape anisotropy of the magnetic shields and their magnetostatic coupling with the free-layer. A fourth function is to render the cells less sensitive to external magnetic fields by decreasing the net magnetization of the cell. All in all, the magnetic shields allow faster, more efficient and more deterministic switching of the cell than with in-plane and perpendicular STT-MRAM cells without the magnetic shields. They also add to the three-dimensional aspect of the cells.

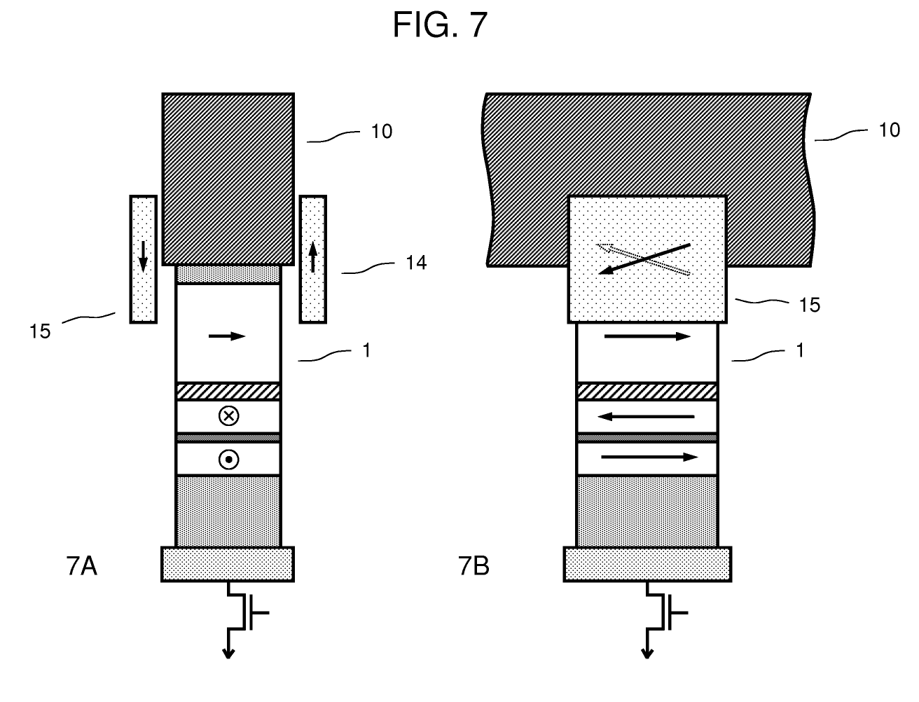

Other embodiment of Cell 3 is shown in FIG. 7. In this case the magnetostatic interaction between the magnetic shields and the free-layer produces two stable magnetization configurations slightly misaligned with respect to the easy axis of those elements, as shown with arrows. The dotted arrow represents the direction of the stable net magnetization of shield 14, at the opposite side of the cell. The magnetization of the fixed-layer would be fixed in the direction of its easy axis.

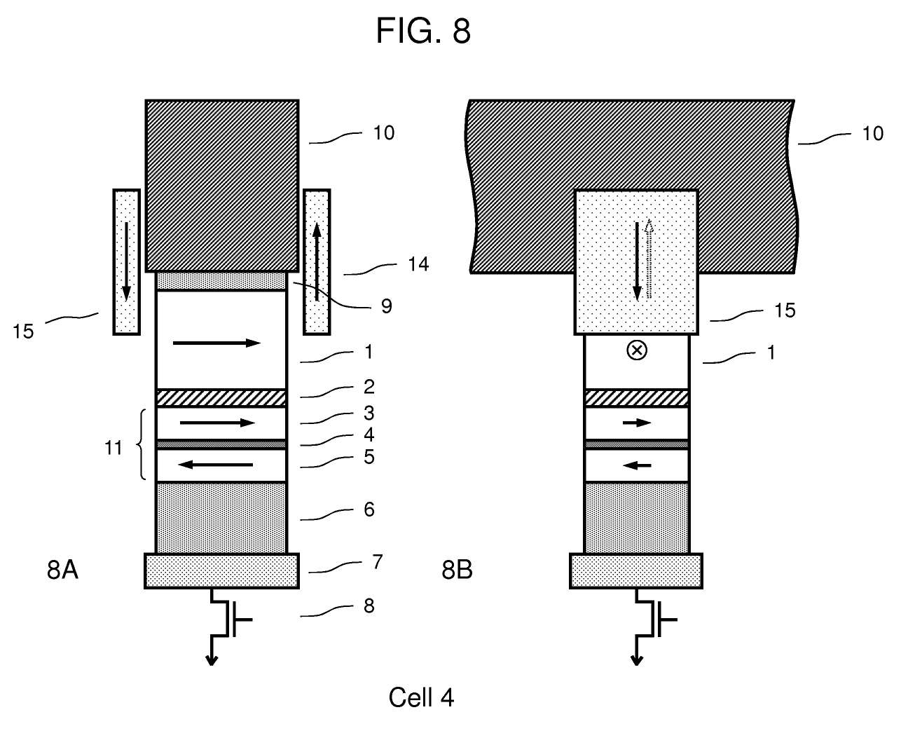

Cell 4, shown in FIG. 8, represents another embodiment of a cell with in-plane geometry, similar to Cell 3. In this case, the equilibrium magnetizations of the magnetic shields are oriented perpendicularly and still form a close loop with the free-layer's magnetization. In this configuration the magnetic shields play a larger role in the thermal stability of the cell. In some embodiments the free-layer would not have shape anisotropy, and the thermal stability of the cell would be produced by the shape anisotropy of the magnetic shields and their magnetostatic interaction with the free-layer. In other embodiments the free-layer would have some in-plane shape anisotropy so that it would be responsible for a larger portion of the thermal stability of the cell.

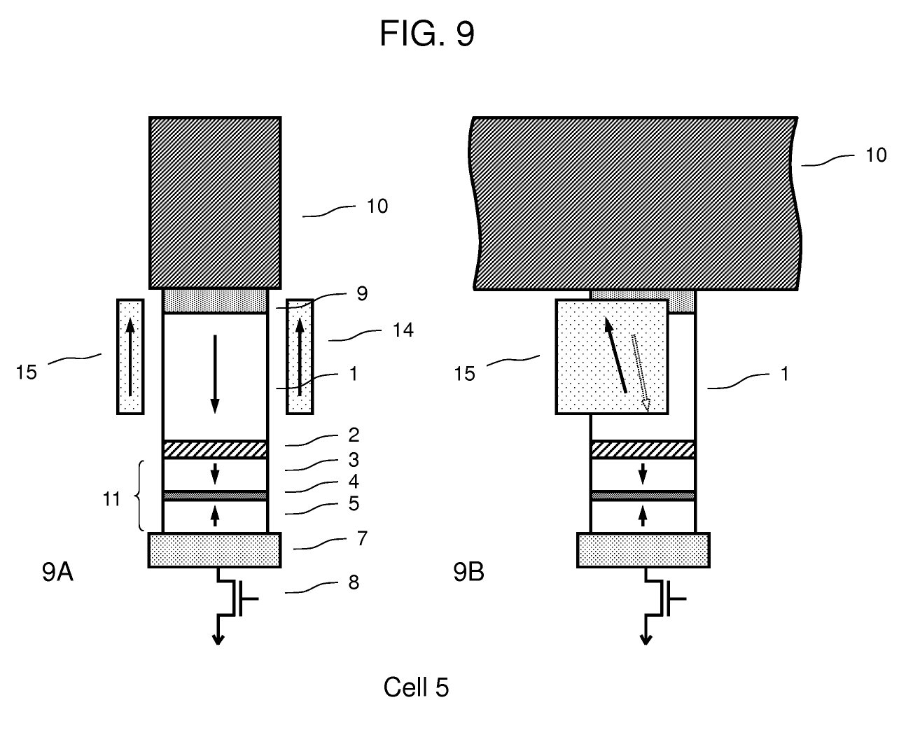

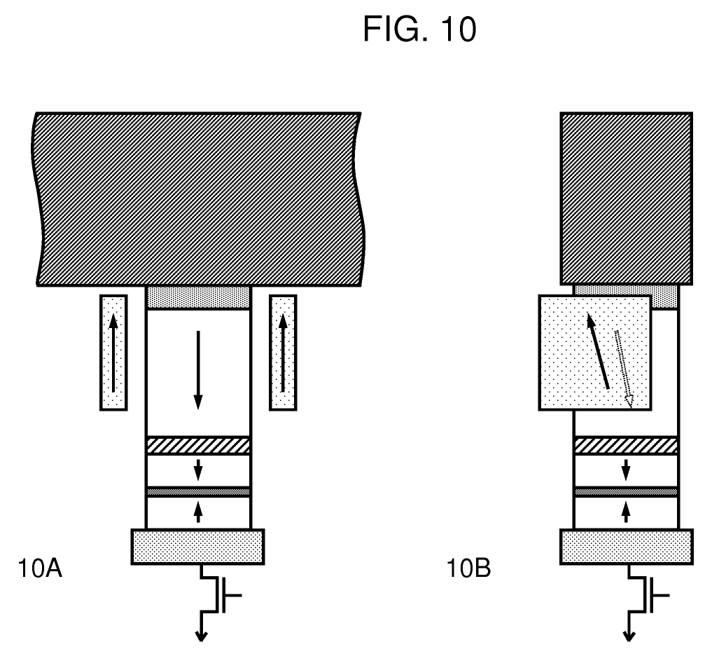

The magnetic shields concept can also be applied to Cell 2 which has perpendicular orientation. That is represented as Cell 5 in FIG. 9. It should be noticed in FIG. 9B that the magnetic shields are placed a bit diagonally off-centered from the free-layer. That is to enhance the dampening that occurs between the free-layer and the magnetic shields and to tilt the free-layer's magnetization away from the perpendicular direction, as shown with the dotted arrow. The direction of the magnetizations within the magnetic shields 14 and 15 would be roughly the same. As mentioned before, an initial non-zero angle between the magnetizations of the fixed-layer and the free-layer produces faster and more deterministic switching as compared to a parallel alignment. For Cell 5, the orientation of the bit-line 10 respect to the magnetic shields can be any. As an illustration of that, FIG. 10 shows the bit-line oriented 90 degrees respect to the one shown in FIG. 9.

Cell 5 configuration has the advantage of Cell 3 of allowing very low write current and very fast and deterministic switching. This is because as with Cell 3, the thermal stability of the cell is given by the non-planar shape anisotropy and the magnetostatic interaction of the free-layer with the magnetic shields, and not material-property-based. That and the dampening and switching characteristics of the magnetic shields allow for the lowest possible damping constant in the free-layer and thus the smallest STT write current with very deterministic switching. Cell 5 however, has the advantage over Cell 3 of facilitating larger memory density. This is because the perpendicular orientation produces much lower magnetostatic bit-to-bit disturb and a smaller MTJ area, as it is not elongated in the plane.

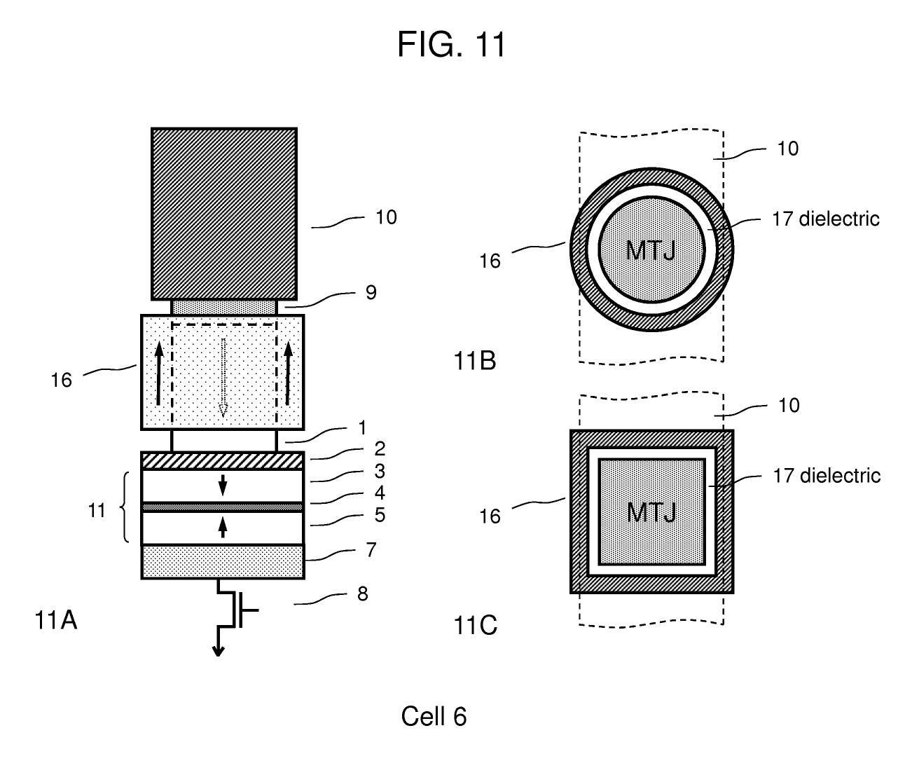

An extension of perpendicular 3D-MRAM cells with magnetic shields is presented in Cell 6 (FIG. 11). In this case the magnetic shield 16 wraps around the free-layer, separated by a dielectric layer 17, that prevents any significant exchange coupling between the free-layer and the magnetic shield. In some embodiments, the in-plane shape of the free-layer is a circle as in FIG. 11B. In others, it is a square as in FIG. 11C. In other embodiments the shape is a square with rounded corners. The shape is not limited to the ones mentioned here, as long as the in-plane shape does not generate a significant magnetic anisotropy. The in-plane orientation of the bit-line 10 respect to the MTJ's orientation can be any.

In a preferred embodiment, the magnetization in the magnetic shield should naturally tend to form an in-plane closed loop if it were magnetically isolated. However, under the magnetic field and anisotropy of the free-layer it should assume a perpendicular anti-ferromagnetic configuration with the free-layer. The barrier height is then the result of the magnetostatic interaction of these two ferromagnetic elements.

As with Cell 2, the free-layer for Cells 5 and 6 can be composed of a single ferromagnetic layer or it can be composed of the two layers 12 and 13 shown in FIG. 4. These layers 12 and 13 would have the same function they have for Cells 1-4.

All the cells herein described allow designing memory devices with cells of different levels of data retention within the same chip, with the purpose of reducing energy consumption in various applications. Data retention is controlled by the height of the thermal barrier of the cell which, in all the cells described in this invention, is controlled through shape anisotropy and magnetostatics. For the cells with in-plane anisotropy, barrier height is easily controlled through the aspect ratio of the free-layer. For the cells with perpendicular anisotropy, barrier height can be controlled through the area of the free-layer, which is the way of changing the free-layer's aspect ratio for the cells lying in the same plane across a device. Cells lying in different planes could use different free-layer thickness to achieve different aspect ratio instead.

One skilled in the art would recognize that the cells herein described can be manufactured using conventional front-end and back-end CMOS manufacturing techniques.

What it is claimed is:

1. A method for reducing the switching current of spin transfer torque magnetic random access memory (STT-MRAM) devices through a non-planar shape anisotropy of the memory cell's free-layer (3D-free-layer) that has little to none easy plane magnetic anisotropy and hence mostly or only having just the anisotropy field needed for the thermal stability of the cell and a magnetic behavior much closer to the advantageous bulk behavior than with thin film geometry.

2. Embodiments of the method of claim 1 where the free-layer has a closely symmetric or fully symmetric shape, like a square or a circle, in two of the three orthogonal dimensions of space and a longer size in the remaining orthogonal direction, being the edges along this direction either sharp or rounded as well.

3. 3D-MRAM cells, comprising a multitude of layers and structures, nominally:
an access transistor,
a non-magnetic bottom electrode connected to the access transistor,
a fixed magnet structure (fixed-layer),
a 3D-free-layer as in claim 1, the magnetization of which can be switched between two opposite stable configurations by the appropriate write current,
a dielectric tunneling layer that separates the magnetic free-layer from the fixed-layer,
a top non-magnetic electrode in direct contact with the free magnetic layer,
a metal line that connects the cell on the top, and
optional patterned magnetic elements that do not carry electric current (magnetic shields) magnetostatically coupled to the free-layer.

4. Embodiments of a 3D-free-layer layer structure of claim 1 comprising a single layer of ferromagnetic material which deals with magneto-resistance and damping coefficient.

5. Embodiments of a 3D-free-layer layer structure of claim 1 comprising two consecutive layers of ferromagnetic materials, with the layer next to the tunnel barrier being a thin layer that allows high tunneling magneto-resistance and the other being a thick layer that creates the no-easy-plane anisotropy effect of claim 1 and having low damping constant and/or when viable, much lower saturation magnetization than the thin layer.

6. The simplest embodiment of a 3D-MRAM cell configuration of claim 3 with in-plane orientation of the equilibrium magnetization in the ferromagnetic layers (Cell 1), where the fixed magnet structure is a synthetic anti-ferromagnet (SAF) pinned by an anti-ferromagnet (AF) layer and having no magnetic shields.

7. The preferred orientation of the fixed-layer magnetization relative to the free-layer's easy axis for in-plane oriented 3D-MRAM cells of claim 3, which is forming an angle smaller than ±45 (or between 180±45) degrees but not close to 0 (or 180) degrees, as this feature allows more deterministic and faster switching through spin transfer torque and also allows lower switching current than with the conventional 0/180 degrees orientation.

8. The simplest embodiment of a 3D-MRAM cell configuration of claim 3 with perpendicular orientation of the equilibrium magnetization in the ferromagnetic layers (Cell 2), where the fixed magnet structure is a multilayer synthetic anti-ferromagnet with very high perpendicular magnetic anisotropy (perpendicular SAF) that cannot be switched with the switching current and having no magnetic shields.

9. An embodiment of the magnetic shields of claim 3, consisting of two thin parallel patterned ferromagnetic elements placed at opposite sides of the cell, in close proximity to the free-layer and coupled to the latter through magnetostatic coupling and having magnetizations that switch along with the magnetization of the free-layer, induced by the magnetic field of said free-layer.

10. An embodiment of a 3D-MRAM cell configuration of claim 3 with in-plane orientation of the equilibrium magnetization in the ferromagnetic layers, where the fixed magnet structure is an SAF pinned by an AF layer and having magnetic shields (Cell 3) in anti-ferromagnetic configuration with the free-layer of the cell.

11. An embodiment of Cell 3 from claim 10 with a different magnetization configuration in the ferromagnetic layers in which the orientation of the magnetization in the fixed-layer is parallel to the long axis of the free-layer and the magnetization of the free-layer and magnetic shields somewhat departing from said parallel direction due to the equilibrium produced by the shape anisotropy of these layers and the magnetostatic field between them.

12. A method for dampening the magnetization ringing in the free-layer during switching and disturb, and of making the switching event faster and more deterministic by having high Gilbert damping constant (much higher than in the cell's free-layer) in the magnetic shields of claim 3.

13. A method for reducing the magnetostatic disturb among MRAM cells, through the use of the “magnetic shields” of claim 3, by with such purpose, adjusting the shape, position and magnetization of said magnetic shields.

14. A method for increasing or reducing the overall thermal stability of the cell by adjusting the magnetic shape anisotropy of the magnetic shields of claim 3 in conjunction with their magnetostatic interaction with the cell's free-layer, as compared to the thermal stability of the same cell without said magnetic shields.

15. An embodiment of 3D-MRAM cell configuration (Cell 4) of claim 3, having the stable magnetization in the magnetic shields oriented in the vertical direction and the magnetization in the free-layer oriented in-plane forming a closed loop and having an in-plane SAF pinned by an AF as fixed-layer.

16. An embodiment of 3D-MRAM cell configuration (Cell 5) of claim 3, having magnetic shields, and with stable magnetization in the free-layer oriented close to the perpendicular direction but tilted due to off-center placement of the magnetic shields respect to the rest of the cell, and with the fixed-layer composed of a perpendicular SAF.

17. An embodiment of 3D-MRAM cell configuration (Cell 6) of claim 3, having stable magnetization of the ferromagnetic components in the perpendicular direction, including a perpendicular SAF as a fixed-layer, and having a one-piece magnetic shield wrapped around the 3D-free-layer.
